(19) United States
(12) Patent Application Publication
(10) Pub. No.: US 2025/0192521 A1
(43) Pub. Date: Jun. 12, 2025

(54) LIGHT-EMITTING DIODE

(71) Applicant: ams-OSRAM International GmbH, Regensburg (DE)

(72) Inventors: Bruno JENTZSCH, Regensburg (DE); Christoph EICHLER, Donaustauf (DE); Harald KÖNIG, Bernhardswald (DE); Georg BRÜDERL, Burglengenfeld (DE); Urs HEINE, Regensburg (DE); Sven GERHARD, Alteglofsheim (DE)

(73) Assignee: ams-OSRAM International GmbH, Regensburg (DE)

(21) Appl. No.: 18/847,193

(22) PCT Filed: Mar. 15, 2023
(86) PCT No.: PCT/EP2023/056586

§ 371 Date: Sep. 13, 2024

(30) Foreign Application Priority Data
Mar. 16, 2022 (DE) 10 2022 106 173.6

(51) Int. Cl. H01S 5/32; H01S 5/042

(52) U.S. Cl. CPC H01S 5/3214; H01S 5/04256

(57) ABSTRACT

A light-emitting diode is specified which includes a semiconductor layer sequence grown in a vertical direction and having an active layer, which is configured and provided to generate light in an active region during operation, and a transparent, at least partly electrically conductive cladding layer structure arranged directly on the semiconductor layer sequence in the vertical direction, wherein the cladding layer structure comprises at least a first cladding layer, a second cladding layer and a third cladding layer.

### CROSS-REFERENCE TO RELATED APPLICATIONS

The present application is a national stage entry from International Application No. PCT/EP2023/056586, filed on Mar. 15, 2023, published as International Publication No. WO 2023/174995 A1 on Sep. 21, 2023, and claims priority to German Patent Application No. 10 2022 106 173.6, filed Mar. 16, 2022, the disclosures of all of which are hereby incorporated by reference in their entireties.

### FIELD

A light-emitting diode is specified. For example, the light-emitting diode can be a semiconductor laser diode.

### BACKGROUND

Laser diodes are known which have a layer of a transparent electrically conducting oxide. Typically, such a layer is provided with a large thickness, as this can improve the ageing stability of the laser diode. However, transparent electrically conducting oxides have a large absorption coefficient, which can affect efficiency.

At least one object of certain embodiments is to provide a light-emitting diode.

These objects are achieved by the subject-matters according to the independent claims. Advantageous embodiments and developments of the method and the subject-matter are characterized in the dependent claims, and are also disclosed by the following description and the drawings.

### SUMMARY

According to at least one embodiment, a light-emitting diode, which can be particularly preferably as a semiconductor laser diode or as a superluminescent diode, has at least one active layer which is configured and intended to generate light in an active region during operation. The active layer can in particular be part of a semiconductor layer sequence with a plurality of semiconductor layers and have a main extension plane which is perpendicular to an arrangement direction of the layers of the semiconductor layer sequence. For example, the active layer can have exactly one active region. Furthermore, the active layer can also have a plurality of active regions. The formation of an active region in the active layer can be effected by one or more elements defining an active region. The term “at least one active region” used in the following can refer to embodiments with exactly one active region as well as embodiments with a plurality of active regions.

According to a further embodiment, the light-emitting diode has a light-outcoupling surface and a rear surface opposite the light-outcoupling surface. The light-outcoupling surface and the rear surface can in particular be side surfaces of the light-emitting diode and particularly preferably side surfaces of the semiconductor layer sequence, which can also be referred to as so-called facets. During operation, the light-emitting diode can emit the light generated in at least one active region via the light-outcoupling surface. The light-emitting diode can therefore preferably be configured as an edge-emitting semiconductor laser diode. Suitable optical coatings, in particular reflective or partially reflective layers or layer sequences, can be applied to the light-outcoupling surface and the rear surface for this purpose, which can form an optical resonator for the light generated in the active layer. Alternatively, no optical resonator can be formed. In this case, the light-emitting diode can be configured as a superluminescent diode. The features described below apply equally to any embodiment of the light-emitting diode, which can be configured as described, for example as a semiconductor laser diode or as a superluminescent diode.

The at least one active region can extend between the rear surface and the light-outcoupling surface along a direction referred to herein and hereinafter as the longitudinal direction. The longitudinal direction can in particular be parallel to the main extension plane of the active layer. The direction in which the layers are arranged above each other, i.e. a direction perpendicular to the main extension plane of the active layer, is referred to here and in the following as the vertical direction. A direction perpendicular to the longitudinal direction and perpendicular to the vertical direction is referred to here and in the following as the transversal direction. The longitudinal direction and the transversal direction can thus span a plane that is parallel to the main extension plane of the active layer. Directions parallel to this plane can also be referred to as lateral directions in the following, so that the longitudinal direction and the transversal direction are also lateral directions.

In particular, the semiconductor layer sequence can be embodied as an epitaxial layer sequence, i.e. as an epitaxially grown semiconductor layer sequence. The semiconductor layer sequence can, for example, be based on InAlGaN. InAlGaN-based semiconductor layer sequences are particularly those in which the epitaxial semiconductor layer sequence generally comprises a layer sequence of different individual layers, which contains at least one individual layer comprising a material from the III-V compound semiconductor material system InₓAl_{y}Ga_{1-x-y}N with 0≤x≤1, 0≤y≤1 and x+y≤1. In particular, the active layer can be based on such a material. Semiconductor layer sequences that have at least one active layer based on InAlGaN can, for example, preferentially emit electromagnetic radiation in an ultraviolet to green wavelength range.

Alternatively or additionally, the semiconductor layer sequence can also be based on InAlGaP, i.e. the semiconductor layer sequence can have different individual layers, of which at least one individual layer, for example the active layer, has a material from the III-V compound semiconductor material system InₓAl_{y}Ga_{1-x-y}P with 0≤x≤1, 0≤y≤1 and x+y≤1. Semiconductor layer sequences that have at least one active layer based on InAlGaP can, for example, preferentially emit electromagnetic radiation with one or more spectral components in a green to red wavelength range.

Alternatively or additionally, the semiconductor layer sequence can also comprise other III-V compound semiconductor material systems, for example an InAlGaAs-based material, or II-VI compound semiconductor material systems. In particular, an active layer comprising an InAlGaAs-based material can be capable of emitting electromagnetic radiation having one or more spectral components in a red to infrared wavelength range. A II-VI semiconductor compound material can have at least one element from the second main group, such as Be, Mg, Ca, Sr, and one element from the sixth main group, such as O, S, Se. For example, the II-VI compound semiconductor materials include ZnSe, ZnTe, Zno, ZnMgO, CdS, ZnCdS and MgBeO.

In a method for manufacturing the light-emitting diode, a semiconductor layer sequence can be provided in particular, which has an active layer that is configured and intended to generate light during operation of the light-emitting diode. In particular, the semiconductor layer sequence with the active layer can be produced by means of an epitaxy process. The embodiments and features described above and below apply equally to the light-emitting diode and to the method for producing the light-emitting diode.

The active layer and, in particular, the semiconductor layer sequence with the active layer can be applied to a substrate. For example, the substrate can be configured as a growth substrate on which the semiconductor layer sequence is grown. The active layer and, in particular, the semiconductor layer sequence with the active layer can be produced by means of an epitaxy process, for example by means of metal-organic vapor-phase epitaxy (MOVPE) or molecular beam epitaxy (MBE). In particular, this can mean that the semiconductor layer sequence is grown epitaxially on the growth substrate. Furthermore, the semiconductor layer sequence can be provided with electrical contacts in the form of one or more contact layers. In addition, it can also be possible for the growth substrate to be removed after the growth process. In this case, for example, the semiconductor layer sequence can also be transferred to a substrate configured as a carrier substrate after the growth process. The substrate can comprise a semiconductor material, for example a compound semiconductor material system mentioned above, or another material. In particular, the substrate can comprise sapphire, GaAs, GaP, GaN, InP, SiC, Si, Ge and/or a ceramic material such as SiN or AlN or be made of such a material.

The active layer can, for example, have a conventional p-n junction, a double heterostructure, a single quantum well structure (SQW structure) or a multiple quantum well structure (MQW structure) for light generation. In addition to the active layer, the semiconductor layer sequence can comprise further functional layers and functional regions, such as p-or n-doped charge carrier transport layers, i.e. electron or hole transport layers, undoped or p-or n-doped confinement, cladding or waveguide layers, barrier layers, planarization layers, buffer layers, protective layers and/or electrode layers, as well as combinations thereof.

Furthermore, additional layers, such as buffer layers, barrier layers and/or protective layers can also be arranged perpendicular to the growth direction of the semiconductor layer sequence, for example around the semiconductor layer sequence, i.e. on the side surfaces of the semiconductor layer sequence.

According to a further embodiment, the light-emitting diode has a cladding layer structure. The cladding layer structure is not part of the semiconductor layer sequence grown, particularly preferably epitaxially, but is applied by means of a non-epitaxial method, for example overgrowth by non-epitaxial chemical vapor deposition, sputtering, vapor deposition and/or a sol-gel method. In particular, the semiconductor layer sequence has a top surface in the form of an interface as viewed from the active layer in a vertical direction, with which the semiconductor layer sequence terminates in this vertical direction and which can also be referred to below as the epitaxy top side. The epitaxy top side can thus be a top side of the semiconductor layer sequence facing away from the active layer in the vertical direction, to which the cladding layer structure is applied. Particularly preferably, the cladding layer structure can be arranged directly on the semiconductor layer sequence and thus directly on the epitaxy top side.

According to a further embodiment, the cladding layer structure is transparent and at least partially electrically conducting. Optical properties such as, for example, a transparency, an absorption coefficient and a refractive index of, for example, a material or a layer refer, unless otherwise stated, to the wavelength of the light generated in the active layer during operation. In particular, “the wavelength” can refer to a characteristic wavelength such as the peak wavelength or the average wavelength or even the wavelength range of the light generated in the active layer. In particular, “transparent” can refer to a layer or layer structure that has a transmission coefficient of greater than or equal to 50% or greater than or equal to 75% or greater than or equal to 90% or preferably greater than or equal to 95% or particularly preferably greater than or equal to 99%.

The cladding layer structure can be applied in a large-area manner on the previously described epitaxy top side of the semiconductor layer sequence. This can mean, for example, that the cladding layer structure is configured continuously and completely covering the entire epitaxy top side. Furthermore, the semiconductor layer sequence can have a current injection region, i.e. a surface area of the epitaxy top side via which exclusively or at least essentially the entire electric current for operating the light-emitting diode is injected into the semiconductor layer sequence from the side of the cladding layer structure. “Essentially the entire electric current” can particularly preferably mean a proportion of greater than or equal to 90% or greater than or equal to 95% or particularly preferably greater than or equal to 99% of the electric current that is injected into the semiconductor layer sequence from the cladding layer structure. This can be achieved, for example, by ensuring that the electrical contact resistance between the cladding layer structure and the current injection region is lower than in areas of the epitaxy top side that are not part of the current injection region. Influencing the electrical contact resistance can be achieved, for example, by one or more measures, which can be selected from laterally varying doping, laterally varying layer composition, surface structures, surface damage and structured electrically insulating or at least poorly conducting layers on the epitaxy top side. The cladding layer structure can be arranged in a large-area manner at least on the current injection region or also exclusively on the current injection region. The current injection region can influence the formation of an active region in the active layer and thus be an element defining the active region.

According to a further embodiment, the cladding layer structure has at least a first cladding layer or is formed by the first cladding layer. Furthermore, the cladding layer structure can have several cladding layers and is particularly preferably formed by several cladding layers. Cladding layers are referred to here and in the following in particular as those layers which have an optical effect on the optical wave of the light generated in the active layer, for example on waveguiding and mode structure. A transparent layer that is so far away from the active layer that it has no influence on the light generated in the active layer because the optical wave has already decayed too much at the position it reaches this layer can no longer be understood as a cladding layer in the sense of the present description.

According to a further embodiment, the cladding layer structure has a first cladding layer, which is particularly preferably arranged directly on the semiconductor layer sequence, i.e. in particular directly on the epitaxy top side of the semiconductor layer sequence. The first cladding layer can in particular be arranged in a large-area manner and thus unstructured on the epitaxy top side. Furthermore, it is possible that the first cladding layer is arranged unstructured at least on the current injection region or exclusively on the current injection region. At least the current injection region can be completely covered by the first cladding layer. The current injection region can, for example, be formed by at least a part of a top side of a ridge waveguide structure facing away from the active layer in the semiconductor layer sequence, so that the first cladding layer can be applied in a large-area manner at least on such a ridge top side. Furthermore, it is also possible that the current injection region does not include edge regions of the top side of the ridge waveguide structure, so that the first cladding layer is applied to the entire top side except for edge regions which can be adjacent to side surfaces of the ridge waveguide structure and/or to facets of the semiconductor layer sequence. Furthermore, it is also possible for the first cladding layer to have openings or to be in the form of islands.

Particularly preferably, the cladding layer structure has no further layer, i.e. no further cladding layer, which protrudes beyond the first cladding layer in a lateral direction. In other words, the cladding layer structure can have a maximum lateral expansion that corresponds to a maximum lateral expansion of the first cladding layer.

According to a further embodiment, the cladding layer structure has a second cladding layer. The second cladding layer is arranged directly on the first cladding layer and is structured. In other words, the second cladding layer is not arranged in a large-area manner and thus does not completely cover the first cladding layer. In particular, the first cladding layer can be covered by the second cladding layer in at least a first partial region and can be uncovered by the second cladding layer in at least a second partial region. The at least one first partial region and the at least one second partial region are particularly preferably directly adjacent to one another. For example, a plurality of first partial regions can also be present. Each of the plurality of first partial regions can be directly adjacent to at least one or a plurality of second partial regions. Alternatively or additionally, a plurality of second partial regions can also be present. Each of the plurality of second partial regions can be directly adjacent to at least one or a plurality of first partial regions. In the case of a plurality of first partial regions, these can particularly preferably be separated from one another by one or more second partial regions. In the case of a plurality of second partial regions, these can be separated from one another by one or more first partial regions. In particular, the first cladding layer can have a top side facing away from the active layer, the surface of which is formed entirely from first and second partial regions. The features described here and in the following for the first and second partial regions can apply regardless of the number of first and second partial regions, for example in cases where there is exactly one first partial region or exactly one second partial region or a plurality of first partial regions or a plurality of second partial regions.

For example, there can be exactly one first partial region and a plurality of second partial regions, the second partial regions being separate from one another and each of the second partial regions being surrounded by the first partial region in the lateral direction. In this case, the second cladding layer is thus configured continuously and has a plurality of openings above the second partial regions. Conversely, there can be exactly one second partial region and a plurality of first partial regions, wherein the first partial regions are separate from each other and each of the first partial regions is surrounded by the second partial region in the lateral direction. In this case, the second cladding layer is thus formed in the form of a plurality of islands which are separated from each other on the first cladding layer by the configured continuously second partial region. At least one or more or each of the openings or islands can, for example, be point-like with a circular or polygonal cross-section. Furthermore, at least one or more or each of the openings or islands can be formed in the shape of a strip with a main direction of extension in the longitudinal or transversal direction, i.e. as longitudinal or transverse strips. The openings or islands, i.e. also the second partial regions or the first partial regions, can be arranged uniformly in the longitudinal and/or transversal direction, i.e. with the same sizes and/or the same cross-sectional shapes and the same distances from one another. The openings or islands, i.e. also the second partial regions or the first partial regions, can thus be arranged, for example, in a regular dot pattern or a regular striped pattern. For example, a plurality of second partial regions can be present, wherein the second partial regions are regularly arranged in longitudinal directions with a spacing corresponding to an integer multiple of half a wavelength of the light generated in the active layer, taking into account the effective refractive index. In addition, the openings or islands can be irregularly shaped, i.e. have different sizes and/or different distances from each other and/or different cross-sectional shapes.

Furthermore, the second cladding layer can cover at least 50% or at least 75% or, particularly preferably, at least 90% and less than 100% of the first cladding layer. The sum of the surface areas of all first partial regions can thus be at least 50% or at least 75% or, particularly preferably, at least 90% and less than 100% of the total surface area of the first cladding layer. The openings or islands, i.e. also the second partial regions or the first partial regions, can preferably have a size in the lateral direction, in particular a diameter or a width, of less than or equal to 20 μm or less than or equal to 5 μm and of greater than or equal to 1 μm.

According to a further embodiment, the cladding layer structure has a third cladding layer. The third cladding layer can be arranged directly on the first cladding layer at least in the at least one second partial region. For example, the third cladding layer can be arranged only on the at least one second partial region and the at least one first partial region can be free of the third cladding layer. In this case, the second and third cladding layers can have an equal thickness, with the third cladding layer being arranged only in the lateral direction next to regions with the second cladding layer. In this case, the top side of the cladding layer structure facing away from the active layer is formed by areas with the material of the second cladding layer and the material of the third cladding layer arranged next to each other. Furthermore, it is also possible that the third cladding layer is also arranged directly on the second cladding layer over the at least one first partial region. In this case, the third cladding layer can cover the second cladding layer. In this case, the top side of the cladding layer structure facing away from the active layer is formed only by the material of the third cladding layer.

According to a further embodiment, the first cladding layer has a thickness which is less than or equal to 200 nm. Unless otherwise specified, a thickness of a layer is measured in a direction perpendicular to the surface area on which said layer is disposed. In particular, the first cladding layer can have a thickness that is greater than or equal to 1 nm and less than or equal to 200 nm. Preferably, the first cladding layer can have a thickness of less than or equal to 70 nm, i.e. in particular a thickness in a range of greater than or equal to 1 nm and less than or equal to 70 nm.

Particularly preferably, the first cladding layer can have a thickness of less than or equal to 30 nm, i.e. in particular a thickness of less than or equal to 30 nm and greater than or equal to 1 nm or greater than or equal to 2 nm. Thus, the first cladding layer can be as thin as possible and have a thickness that is less than one wavelength of the light generated in the active layer, particularly preferably less than 20% of the wavelength of the light generated in the active layer. Figuratively speaking, the first cladding layer can have a thickness that is so small that the optical wave of the light generated in the active layer can penetrate it and the other cladding layers of the cladding layer structure can contribute to waveguiding and mode control.

According to a further embodiment, the second cladding layer has a thickness of less than or equal to 1 μm or less than or equal to 200 nm or less than or equal to 60 nm. Furthermore, the second cladding layer can have a thickness of greater than or equal to 1 nm or greater than or equal to 5 nm or greater than or equal to 10 nm. In particular, the second cladding layer can have a thickness of greater than or equal to 1 nm and less than or equal to 1 μm or greater than or equal to 5 nm and less than or equal to 200 nm or greater than or equal to 10 nm and less than or equal to 60 nm.

According to a further embodiment, the cladding layer structure has a thickness which corresponds to a sum of the thickness of the first cladding layer and the thickness of the third cladding layer, measured in a second partial region. The thickness of the cladding layer structure can thus correspond in particular to the distance between the epitaxial surface of the semiconductor layer sequence and the top side of the cladding layer structure facing away from the active layer. In particular, the cladding layer structure can have a thickness of less than or equal to 1 μm or less than or equal to 400 nm or less than or equal to 300 nm. Furthermore, the cladding layer structure can have a thickness of greater than or equal to 10 nm or greater than or equal to 50 nm or greater than or equal to 100 nm. In particular, the cladding layer structure can have a thickness of greater than or equal to 10 nm and less than or equal to 1 μm or greater than or equal to 50 nm and less than or equal to 400 nm or greater than or equal to 100 nm and less than or equal to 300 nm.

According to a further embodiment, the first cladding layer comprises a transparent, electrically conducting material. Particularly preferably, the first cladding layer has a transparent, electrically conducting oxide (TCO: “transparent conductive oxide”) or is formed from a TCO. Transparent electrically conducting oxides are transparent electrically conducting materials, usually metal oxides, such as zinc oxide, tin oxide, indium oxide, cadmium oxide, titanium oxide, indium oxide or indium tin oxide (ITO). In addition to binary metal oxygen compounds such as zinc oxide (ZnO), tin oxide (SnO₂) or indium oxide (In₂O₃), ternary metal oxygen compounds such as Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs. Particularly preferably, the first cladding layer can comprise one or more of the following materials: ITO, also describable as In₂O₃:Sn, particularly preferably with a proportion of greater than or equal to 90% and less than or equal to 95% of In₂O₃ and greater than or equal to 5% and less than or equal to 10% of SnO₂; In₂O₃; SnO₂; Sn₂O₃; Zno; IZO (indium zinc oxide); GZO (gallium-doped zinc oxide). Furthermore, it is possible that the TCO(s) of the first cladding layer do not necessarily correspond to a stoichiometric composition and can also be p-or n-doped.

Furthermore, the first cladding layer can have a semiconductor material or be made of it. The semiconductor material is not part of the epitaxially grown semiconductor layer sequence, but is applied by a non-epitaxial method described above. For example, the first cladding layer can comprise AlN, AlGaN and/or GaN.

The third cladding layer can comprise a transparent, electrically conducting material, in particular a transparent, electrically conducting oxide and/or a semiconductor material. Particularly preferably, the third cladding layer can comprise or be a material described in connection with the first cladding layer. Particularly preferably, the first cladding layer and the third cladding layer can comprise different materials.

According to a further embodiment, the second cladding layer has a high thermal conductivity. For example, the second cladding layer can comprise or be made of a material that has a thermal conductivity of greater than or equal to 10 W/(m×K) or greater than or equal to 20 W/(m×K). In particular, the second cladding layer can have a thermal conductivity that is greater than the thermal conductivity of the first and/or third cladding layer.

According to a further embodiment, the second cladding layer has a smaller absorption coefficient than the first cladding layer and/or the third cladding layer. For example, the second cladding layer can comprise or be made of a material that has an absorption coefficient of less than or equal to 500/cm or less than or equal to 100/cm or less than or equal to 10/cm.

According to a further embodiment, the second cladding layer has a refractive index that is smaller than a refractive index of the semiconductor layer sequence. Here, the refractive index of the semiconductor layer sequence can result, for example, from an averaged weighting of the refractive indices of the semiconductor layers of the semiconductor layer sequence. Furthermore, the second cladding layer can have an absorption coefficient and a refractive index that are smaller than an absorption coefficient and a refractive index of the first cladding layer and/or the third cladding layer.

According to a further embodiment, the second cladding layer comprises a transparent dielectric material. For example, the second cladding layer can have or be made of a material that is composed of or with an oxide and/or nitride and/or carbide with silicon and/or aluminum such as SiO₂, SiN, SiC, AlN, Al₂O₃. Furthermore, the second cladding layer can, for example, also contain or consist of DLC (“diamond-like carbon”). The cladding layer structure can thus have electrically insulating areas in the form of the second cladding layer, which are embedded in electrically conducting material in the form of the first and third cladding layers.

According to a further embodiment, the second cladding layer has a transparent electrically conducting material, for example a material mentioned in connection with the first cladding layer. For example, the material of the second cladding layer can be selected such that the second cladding layer has a lower electrically conductivity than the first and/or third cladding layer.

At least one or more or each cladding layer of the cladding layer structure, i.e. at least one or more or each layer selected from the first cladding layer, the second cladding layer and the third cladding layer, can comprise one or more of the materials mentioned in each case. If a cladding layer has several materials, these can, for example, be arranged in the form of a layer structure in a vertical direction on top of one another and/or in laterally adjacent areas.

According to a further embodiment, the light-emitting diode has a metallic contact layer arranged on the cladding layer structure. One or more metals selected from Au, Pt, Ag, Pd, Rh and Ni, for example, can be suitable as materials for the metallic contact layer.

The metallic contact layer is particularly preferably arranged directly on the cladding layer structure. In other words, the top side of the cladding layer structure facing away from the active layer can be in direct contact with the metallic contact layer. For example, the metallic contact layer can be arranged in a large-area manner on the cladding layer structure. Alternatively, the metallic contact layer can be arranged in a structured manner on the cladding layer structure. For example, the metallic contact layer can cover the current injection region. In this case, the metallic contact layer can also cover the active region in particular. Furthermore, the metallic contact layer can be arranged in a lateral direction only next to the current injection region and/or the active region. In this case, the metallic contact layer can be configured in such a way that the current injection region is not covered by the metallic contact layer in a vertical direction. In this case, only a dielectric layer can be arranged on the cladding layer structure in a vertical direction above the active region, so that the current injection region can be covered by the dielectric layer, or the cladding layer structure can be directly adjacent to the surrounding atmosphere in a vertical direction above the active region. The dielectric layer above the active region and/or the surrounding atmosphere can act as a further cladding layer. Furthermore, it is possible that in this case the cladding layer structure only has the first cladding layer. If the first cladding layer is directly adjacent to the surroundings, the light-emitting diode is also free of further cladding layers, particularly in a vertical direction above the cladding layer structure.

In the light-emitting diode described herein with the cladding layer structure with at least the first cladding layer, which is transparent, electrically conducting and has a low thickness as described above, it can be possible, for example, for vertically guided laser modes to experience low internal losses compared to conventional laser diodes, which have much thicker, unstructured TCO cladding layers. In particular, the first cladding layer can serve as a current distribution layer, while the modes can be guided to the greatest possible extent, for example in the second cladding layer, which has lower absorption losses. The first cladding layer is only connected to the third cladding layer in places, wherein it is preferable to ensure a complete supply with current but to connect as little area as possible, for example less than 30%, of the first cladding layer to the third cladding layer. The longitudinal and transverse mode distribution can be influenced by a specific arrangement of the second cladding layer. The cladding layer structure can make it possible to increase the slope, i.e. the ratio of optical power to injected electrical current, and reduce the laser threshold. This can increase the efficiency and service life of the light-emitting diode and reduce costs. It can also be possible to stabilize and/or specifically adjust the wavelength and spectral width as well as the mode distribution. In particular, the light-emitting diode can be used as a semiconductor laser diode with an emission wavelength in the visible or non-visible spectral range.

The light-emitting diode described here can be used, for example as a semiconductor laser diode, in consumer, industrial and automotive applications, for example in projection applications, in material processing and in lighting applications.

Further advantages, advantageous embodiments and further developments are revealed by the embodiments described below in connection with the figures.

### BRIEF DESCRIPTION OF THE DRAWINGS

FIGS. 1A to 1E show schematic illustrations of semiconductor layer sequences for light-emitting diodes and for method steps of methods for manufacturing light-emitting diodes according to several embodiments,

FIG. 2 shows a schematic illustration of a light-emitting diode according to a further embodiment,

FIGS. 3A and 3B show simulations of cladding layer structures of light-emitting diodes according to further embodiments, and

FIGS. 4 to 14 show schematic illustrations of light-emitting diodes according to further embodiments.

### DETAILED DESCRIPTION

In the embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

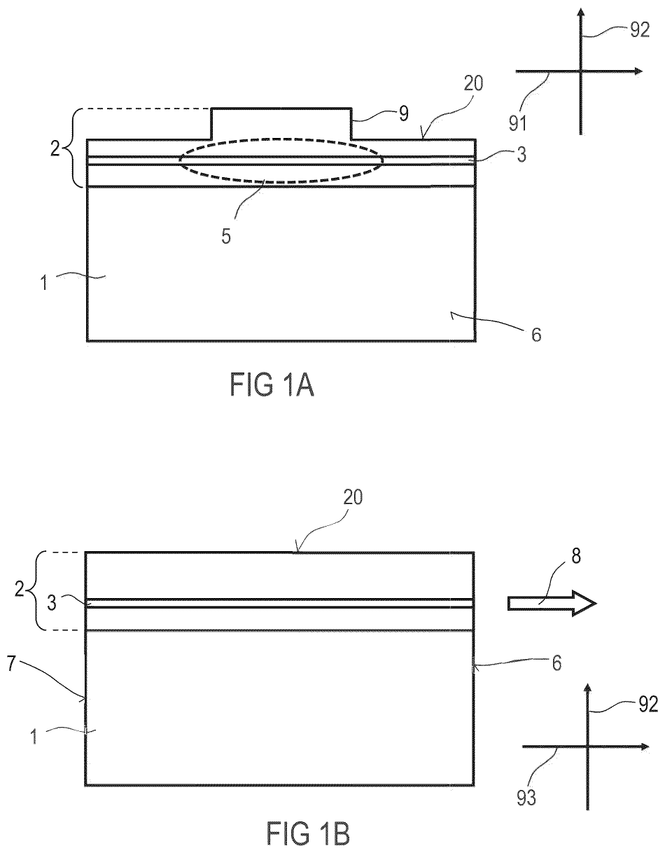

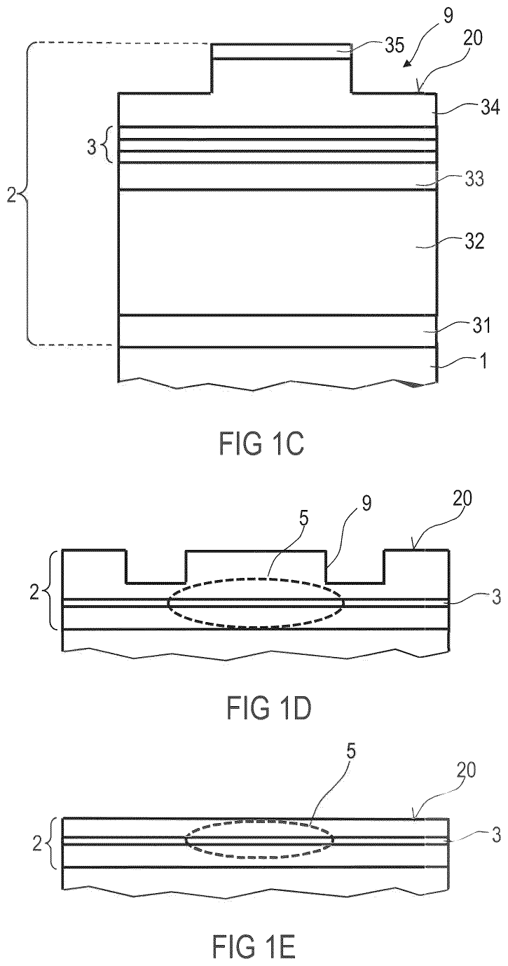

FIGS. 1A to 1E show embodiments of semiconductor layer sequences 2, each on a substrate 1, which are provided and used for the manufacture of the light-emitting diodes described below, wherein FIG. 1A shows a top view of the light-outcoupling surface 6 of the subsequent light-emitting diode and FIG. 1B shows a representation of a section through the semiconductor layer sequence 2 and the substrate 1 with a sectional plane perpendicular to the light-outcoupling surface 6. FIG. 1C shows an embodiment of the structure of the semiconductor layer sequence 2. FIGS. 1D and 1E show modifications of the semiconductor layer sequence 2.

As indicated in FIGS. 1A to 1C, a substrate 1 is provided which is, for example, a growth substrate for a semiconductor layer sequence 2 produced thereon by means of an epitaxy process. Alternatively, the substrate 1 can also be a carrier substrate to which a semiconductor layer sequence 2 grown on a growth substrate is transferred after growth. For example, the substrate 1 can be with or made of GaN, on which a semiconductor layer sequence 2 based on an InAlGaN compound semiconductor material is grown. In addition, other materials, in particular as described in the general part, are also possible for the substrate 1 and the semiconductor layer sequence 2. Alternatively, it is also possible for the finished light-emitting diode to be free of a substrate. In this case, the semiconductor layer sequence 2 can be grown on a growth substrate, which is subsequently removed. The semiconductor layer sequence 2 has an active layer 3, which is suitable for generating light 8 during operation of the finished light-emitting diode and emitting it via the light-outcoupling surface 6. In the case of a light-emitting diode configured as a semiconductor laser diode, laser light can be generated and emitted in particular when the laser threshold is exceeded.

As indicated in FIGS. 1A and 1B, the transversal direction 91 is referred to here and hereinafter as a direction that is parallel to a main extension direction of the layers of the semiconductor layer sequence 2 in a view on the light-outcoupling surface 6. The arrangement direction of the layers of the semiconductor layer sequence 2 on each other and of the semiconductor layer sequence 2 on the substrate 1 is referred to here and in the following as vertical direction 92. The direction perpendicular to the transversal direction 91 and the vertical direction 92, which corresponds to the direction along which the light 8 is emitted during operation of the completed light-emitting diode, is referred to here and in the following as the longitudinal direction 93. Generally, directions parallel to the plane spanned by the transversal direction 91 and the longitudinal direction 93 are referred to as lateral directions.

According to one embodiment, a ridge 9 is formed on the top side of the semiconductor layer sequence 2 facing away from the substrate 1, which, as will be explained further below, is also referred to as the epitaxy top side 20, by removing part of the semiconductor material from the side of the semiconductor layer sequence 2 facing away from the substrate 1. For this purpose, a suitable mask can be applied to the grown semiconductor layer sequence 2 in the area in which the ridge is to be formed. Semiconductor material can be removed using an etching process. The mask can then be removed again. The ridge 9 is formed by such a method in such a way that the ridge extends in the longitudinal direction 93 and is delimited on both sides in the lateral direction 91 by side surfaces, which can also be referred to as ridge side surfaces or ridge sides.

In addition to the active layer 3, the semiconductor layer sequence 2 can have further semiconductor layers, such as buffer layers, cladding layers, waveguide layers, barrier layers, current spreading layers and/or current limiting layers. As shown in FIG. 1C, the semiconductor layer sequence 2 on the substrate 1 can, for example, have a buffer layer 31, a first cladding layer 32 above it and a first waveguide layer 33 above it, on which the active layer 3 is deposited. A second waveguide layer 34 and a semiconductor contact layer 35 can be applied over the active layer 3. Alternatively, the semiconductor contact layer 35 can not be present, for example if at least part of the second waveguide layer 34 is doped accordingly.

In the embodiment shown, the ridge 9 is formed by the semiconductor contact layer 35 and a part of the waveguide layer 34, wherein to produce the ridge 9, a part of the semiconductor layer sequence 2 is removed from the top side 20 after the semiconductor layer sequence 2 has been grown. In particular, the removal can be carried out by an etching process.

The ridge 9 can also be referred to as a ridge waveguide structure or ridge. Due to the refractive index jump on the side surfaces of the ridge 9 to an adjacent material and if it is sufficiently close to the active layer 3, so-called index guiding of the light generated in the active layer 3 can be achieved, particularly when the subsequently completed light-emitting diode is formed as a semiconductor laser diode, which together with the cladding layer structure described below can significantly lead to the formation of an active region 5, which indicates the region in the semiconductor layer sequence 2 in which the generated light is guided and amplified in the form of one or more laser modes during laser operation. The ridge 9 can thus form an element defining the active region. It can also be possible for the ridge 9 to have a lower or greater height than the height shown, i.e. for less or more semiconductor material to be removed to form the ridge 9. For example, the ridge 9 can be formed only by the semiconductor contact layer 35 or a part thereof or by the semiconductor contact layer 35, the second waveguide layer 34, the active layer 3 and a part of the first waveguide layer 33. By adjusting the height of the ridge 9, an adjustment of the index guiding can be achieved. With a decreasing height and/or an increasing distance of the ridge 9 to the active layer 3, the characteristics of the index guiding can be reduced. The mode guiding in the active region is then at least partially achieved by so-called gain guiding.

If the semiconductor layer sequence 2 is based on an InAlGaN compound semiconductor material as described above, the buffer layer 31 can be undoped or n-doped GaN, the first cladding layer 32 can be n-doped AlGaN, the first waveguide layer 33 can be n-doped GaN, the second waveguide layer 34 can be p-doped GaN and the semiconductor contact layer 35 can be p-doped GaN. The n-dopant can be Si, for example, and the p-dopant can be Mg, for example. The active layer 3 can be formed by a pn junction or, as indicated in FIG. 1C, by a quantum well structure with a plurality of layers formed, for example, by alternating layers with or of InGaN and GaN. The substrate can, for example, have or be made of n-doped GaN. Alternatively, other layer and material combinations as described above in the general section are also possible.

Furthermore, reflective or partially reflective layers or layer sequence can be applied to the light-outcoupling surface 6 and the opposite rear surface 7, which form side surfaces of the semiconductor layer sequence 2 and the substrate 1, which are not shown in the figures for the sake of clarity and which are intended and configured to form an optical resonator in the semiconductor layer sequence 2. By forming an optical resonator, the subsequently completed light-emitting diode can be configured as a semiconductor laser diode, in particular as an edge-emitting semiconductor laser diode. In the absence of an optical resonator, the subsequently completed light-emitting diode can, for example, be configured as a superluminescent diode.

As can be seen in FIG. 1A, for example, the ridge 9 can be formed by completely removing semiconductor material laterally on both sides next to the ridge 9. Alternatively, a so-called “tripod” can be formed, as indicated in FIG. 1D, in which the semiconductor material is removed laterally next to the ridge 9 only along two grooves to form the ridge 9. Alternatively, the finished light-emitting diode can also be configured as a so-called broad-area laser diode, in which the semiconductor layer sequence 2 is produced without a ridge or with a ridge of low height and provided for the further process steps. Such a semiconductor layer sequence 2, in which the mode control can be based only or at least essentially on the principle of gain guiding, is shown in FIG. 1E.

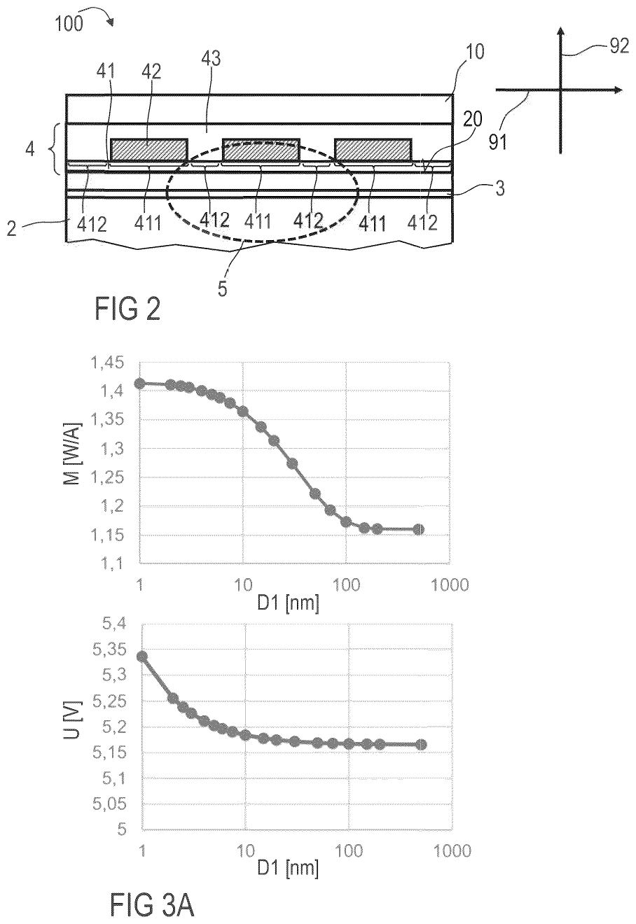

In connection with the further figures, embodiments of a light-emitting diode 100 are described, which can have a semiconductor layer sequence 2 as described above, to which a cladding layer structure 4 is applied. For example, a light-emitting diode 100 with a cladding layer structure 4 is shown in FIG. 2, which can be configured, for example, as a semiconductor laser diode and in which light is generated in an active region 5 during operation. By way of example only, the light-emitting diode 100 is configured without a ridge. Alternatively, a ridge can also be present.

The active region 5 indicated in FIGS. 1A, 1D and 1E is to be understood only schematically, since not only a ridge waveguide structure, if present, but in particular also the cladding layer structure 4 can contribute to its formation, which thus also forms an element defining the active region. In particular, the active region 5, as indicated in FIG. 2, can extend into the cladding layer structure 4. In other words, the optical wave of the light generated in the active layer 3 during operation extends into the cladding layer structure 4.

As already indicated in FIGS. 1A to 1E, the semiconductor layer sequence 2 has, as seen from the active layer 3 in a vertical direction 92, a top side in the form of an interface with which the semiconductor layer sequence 2 terminates in this vertical direction 92 and which can therefore be referred to as the epitaxy top side 20. The epitaxy top side 20 thus forms a top side of the semiconductor layer sequence 2 facing away from the active layer 3, to which the cladding layer structure 4 is applied according to the following embodiments. Particularly preferably, as is indicated in FIG. 2, the cladding layer structure 4 can be arranged directly on the semiconductor layer sequence 2 and thus directly on the epitaxy top side 20.

The cladding layer structure 4 is transparent and at least partially electrically conducting. As a result, during operation of the light-emitting diode 100, current can be injected through the epitaxy top side 20 into the semiconductor layer sequence 2 and thus into the active layer 3 by means of the cladding layer structure 4. For this purpose, a metallic contact layer 10 is applied to the cladding layer structure 4, which serves as an electrical contact element for the electrical connection of the light-emitting diode 10. The metallic contact layer 10 is particularly preferably arranged directly on the cladding layer structure 4 and, as shown in FIG. 2, can be formed in a large-area manner. One or more metals selected from Au, Pt, Ag, Pd, Rh and Ni, for example, can be suitable as materials for the metallic contact layer 10. A further electrical contact element, for example a further metallic contact layer, can for example be present on a side of the substrate facing away from the semiconductor layer sequence 2 or between the substrate and the semiconductor layer sequence 2. The light-emitting diode 100 can thus be configured as a vertical component with regard to electrical contacting.

As shown, the cladding layer structure 4 can be applied in a large-area manner on the epitaxy top side 20 of the semiconductor layer sequence 2. This can mean, for example, that the cladding layer structure 4 is configured continuously and completely covering the entire epitaxy top side 20. In particular, the semiconductor layer sequence 2 can have a current injection region, i.e. a surface area of the epitaxy top side 20 via which exclusively or via which at least essentially the entire electric current for operating the light-emitting diode is injected into the semiconductor layer sequence 2 from the side of the cladding layer structure 4. The current injection region can be formed by the entire epitaxy top side 20 or only by a part of the epitaxy top side 20. The current injection region can be defined, for example, by the fact that the electrical contact resistance between the cladding layer structure and the epitaxy top side 20 is smaller in the current injection region than in regions of the epitaxy top side that are not part of the current injection region. Influencing the electrical contact resistance can be achieved, for example, by one or more measures which can be selected from a laterally varying doping, a laterally varying layer composition, surface structures, surface damage and structured electrically insulating or at least poorly conducting layers on the epitaxy top side 20. The cladding layer structure 4 can be arranged over large areas at least on the current injection region or, alternatively to the embodiment shown, only on the current injection region.

The cladding layer structure 4 has several cladding layers 41, 42, 43, which form the cladding layer structure 4. In particular, the cladding layer structure 4 has a first cladding layer 41. The first cladding layer 41 is particularly preferably arranged directly on the semiconductor layer sequence 2, i.e. in particular directly on the epitaxy top side 20 of the semiconductor layer sequence 2. In the embodiment shown, the first cladding layer 41 is arranged in a large-area manner and thus unstructured on the epitaxy top side 20. Furthermore, it is possible that the first cladding layer 41 is arranged unstructured at least on the current injection region or also exclusively on the current injection region. Thus, at least the current injection region can be completely covered by the first cladding layer 41.

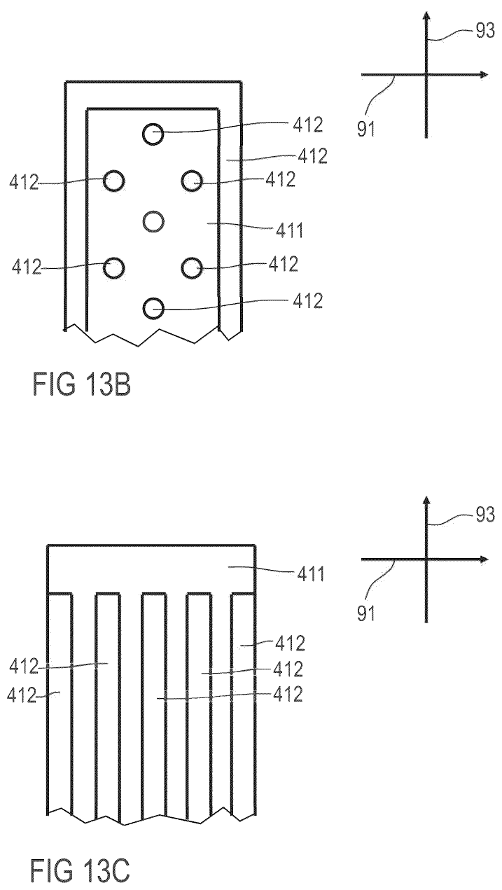

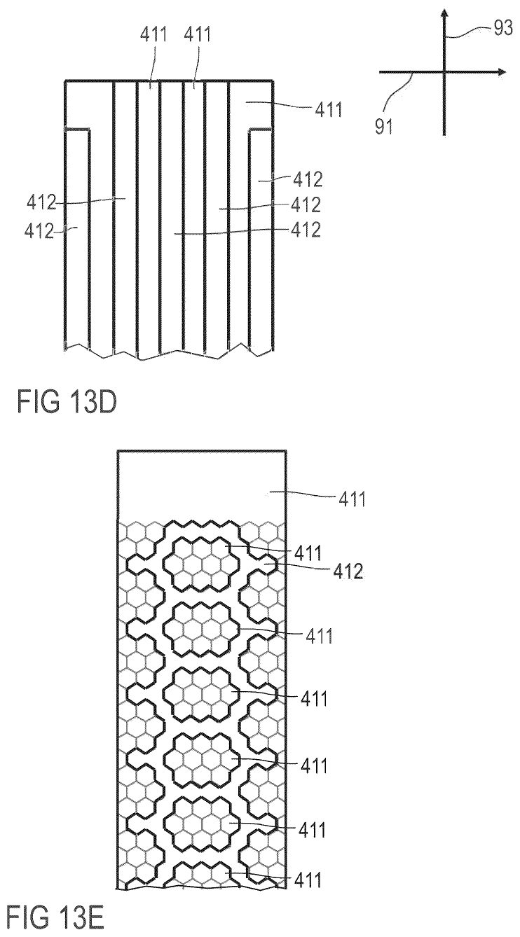

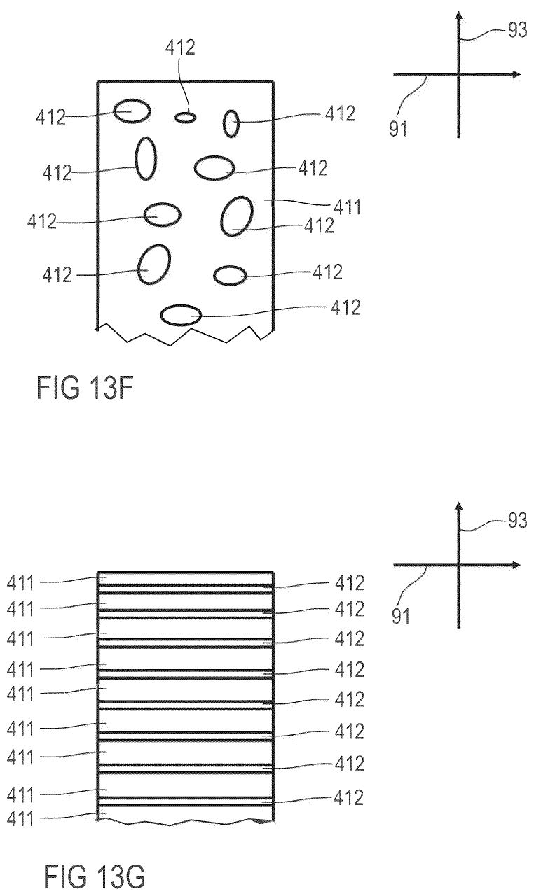

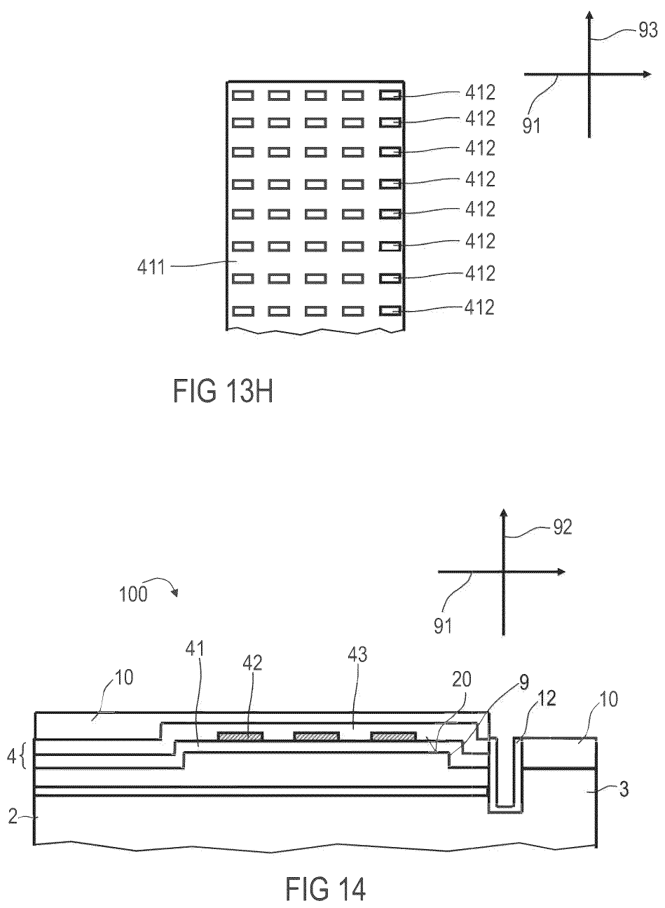

A second cladding layer 42 is arranged on the first cladding layer 41. The second cladding layer 42 is arranged directly on the first cladding layer 41 and is structured. Thus, the second cladding layer 42 is not arranged in a large-area manner and therefore does not completely cover the first cladding layer 41. In particular, the first cladding layer can be covered by the second cladding layer 42 in at least a first partial region 411 and can be uncovered by the second cladding layer 42 in at least a second partial region 412. The at least one first partial region 411 and the at least one second partial region 412 are directly adjacent to each other. For example, a plurality of first partial regions 411 can also be present. Each of the plurality of first partial regions 411 can be directly adjacent to at least one or a plurality of second partial regions 412. Further, a plurality of second partial regions 412 can also be present. Each of the plurality of second partial regions 412 can be directly adjacent to at least one or a plurality of first partial regions 411. In the case of a plurality of first partial regions 411, these can particularly preferably be separated from each other by one or more second partial regions 412. In the case of a plurality of second partial regions 412, these can be separated from each other by one or more first partial regions 411. Particularly preferably, the first cladding layer 41 can have an upper surface facing away from the active layer 3, the surface of which is formed entirely of first and second partial regions 411, 412. Referring to FIGS. 13A to 13H, examples of various configurations and arrangements for the first and second partial regions 411, 412 are shown.

Furthermore, the cladding layer structure 4 has a third cladding layer 43 which is arranged in the at least one second partial region 412 directly on the first cladding layer 411. As shown in FIG. 2, the third cladding layer 43 is also arranged directly on the second cladding layer 42 over the at least one first partial region 411. Thus, the third cladding layer 43 covers the second cladding layer 42 and the second cladding layer 42 can be embedded in between the first and third cladding layers 41, 43, as indicated in FIG. 2. The top side of the cladding layer structure 4 facing away from the active layer 3 is thus formed by the material of the third cladding layer 43.

The first cladding layer 41 serves in particular for an electrical connection of the epitaxy top side 20, so that with the cladding layer structure 4 an electrical current can preferably be injected as uniformly as possible into the semiconductor layer sequence 2 and thus into the active layer 3 via the current injection region provided for this purpose. Thereby, the first cladding layer has, for example, a TCO or is formed from a TCO, for example indium tin oxide (ITO), indium oxide, tin oxide or zinc oxide or another TCO mentioned in the general part. The first cladding layer 41 is not part of the semiconductor layer sequence 2 and can be deposited, for example, by non-epitaxial chemical vapor deposition, sputtering, vapor deposition and/or a sol-gel method. Furthermore, the first cladding layer 41 can alternatively or additionally also comprise or be made of a semiconductor material that is not part of the epitaxially grown semiconductor layer sequence 2, but is applied, for example, by a non-epitaxial method as mentioned above. For example, the first cladding layer 41 can comprise AlN, AlGaN and/or GaN as semiconductor material.

The third cladding layer 43 can be used to establish electrical contact between the first cladding layer 41 and the metallic contact layer 10 independently of the material of the second cladding layer 42. The third cladding layer 43 can have a transparent, electrically conducting material for this purpose, in particular a TCO and/or semiconductor material. Particularly preferably, the third cladding layer 43 can comprise a material described in connection with the first cladding layer 41 or can be made of it. The first cladding layer 41 and the third cladding layer 43 can have the same or preferably different materials.

Although TCO layers on a semiconductor body are also used in the prior art, they are usually used to improve aging stability and therefore have a relatively large thickness within which the optical wave essentially decays completely and thus does not extend into overlying layers, as TCOs typically have high absorption. The overlying layers therefore have no influence on the optical wave. In comparison, the first cladding layer 41 of the cladding layer structure 4 described here has a thickness that is less than or equal to 200 nm. In particular, the first cladding layer 41 can have a thickness that is greater than or equal to 1 nm and less than or equal to 200 nm. Preferably, the first cladding layer 41 can have a thickness of less than or equal to 70 nm, i.e. in particular a thickness in a range of greater than or equal to 1 nm and less than or equal to 70 nm. Particularly preferably, the first cladding layer 41 can have a thickness of less than or equal to 30 nm, i.e. in particular a thickness of less than or equal to 30 nm and of greater than or equal to 1 nm or greater than or equal to 2 nm. For example, the first cladding layer 41 can have a thickness of 10 nm.

Due to the low thickness of the first cladding layer 41 described above, it is possible to reduce the absorption caused by the material of the first cladding layer 41 compared to thicker layers, but still achieve sufficient current distribution in the current injection region. As a result, the material arranged above the first cladding layer 41, i.e. in particular the second cladding layer 42, can provide the actual waveguiding and mode influencing for the optical wave of the light generated in the active layer 3 during operation. In this material, i.e. in particular in the second cladding layer 42, the optical wave can thus at least largely decay.

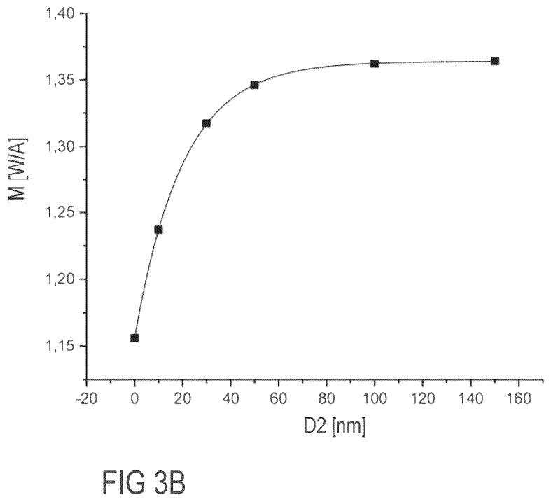

FIG. 3A shows the slope M, i.e. the ratio of optical power to injected electric current, and the electric voltage U of the laser threshold for an exemplary simulated light-emitting diode 100 with the cladding layer structure 4 as a function of the thickness D1 of the first cladding layer 41 made of ITO. For the cladding layer structure 4, a second cladding layer 42 made of SiO₂ with a thickness of 200 nm and a third cladding layer 43 made of ITO with a thickness of 250 nm were also assumed. The thickness of the third cladding layer 43 is measured in a second partial region 412, i.e. from the top of the first cladding layer 41. The area coverage of the second cladding layer 42 on which the simulation was based, i.e. the ratio of the total area of the first partial regions 411 to the total area of the first cladding layer 41, was 80%. It can be seen from the graphs that a thickness of greater than or equal to 1 nm, in particular of greater than or equal to a value between 1 nm and 30 nm, is desirable for a good current extension, while a thickness of less than or equal to 200 nm is advantageous for a large slope with regard to the optical properties, for example a sufficiently low absorption by the first cladding layer 41, which is in agreement with the values given previously.

The second cladding layer 42 preferably has a smaller absorption coefficient than the first cladding layer 41 and/or the third cladding layer 43. Particularly preferably, the second cladding layer 42 can comprise or be made of a material which has an absorption coefficient of less than or equal to 500/cm or less than or equal to 100/cm or even less than or equal to 10/cm. Furthermore, the second cladding layer 42 preferably has a refractive index that is less than a refractive index of the semiconductor layer sequence 2. Furthermore, the second cladding layer 42 can preferably have an absorption coefficient and a refractive index that are smaller than an absorption coefficient and a refractive index of the first cladding layer 41 and/or the third cladding layer 43. Furthermore, it can be advantageous if the second cladding layer 42 has a high thermal conductivity in order to improve cooling of the light-emitting diode 100. For example, the second cladding layer 42 can comprise or be made of a material that has a thermal conductivity of greater than or equal to 10 W/(m×K) or greater than or equal to 20 W/(m×K). In particular, the second cladding layer 42 can have a thermal conductivity that is greater than the thermal conductivity of the first cladding layer 41 and/or the third cladding layer 43.

Particularly preferably, the second cladding layer 42 comprises a transparent dielectric material. For example, the second cladding layer 42 can comprise or be made of a material that is coated with or made of an oxide and/or nitride and/or carbide with silicon and/or aluminum such as SiO₂, SiN, SiC, AlN, Al₂O₃. Furthermore, the second cladding layer 42 can also comprise or be made of DLC, for example. In the case of a dielectric material for the second cladding layer 42, the cladding layer structure 4 thus has electrically insulating regions in the form of the second cladding layer 42, which is embedded in electrically conducting material in the form of the first and third cladding layers. Furthermore, it can be possible for the second cladding layer 42 to have a transparent electrically conducting material, for example a material mentioned in connection with the first cladding layer 41, wherein the material is nevertheless preferably selected such that the optical and thermal properties of the second cladding layer 42 described above are also then achieved. Furthermore, the material of the second cladding layer 42 can also be selected in this case in such a way that the second cladding layer 42 has at least a lower electrically conductivity than the first cladding layer 41 and/or the third cladding layer 43.

The second cladding layer 42 preferably has a thickness of less than or equal to 1 μm or less than or equal to 200 nm or less than or equal to 60 nm. Furthermore, the second cladding layer 42 can have a thickness of greater than or equal to 1 nm or greater than or equal to 5 nm or greater than or equal to 10 nm. In particular, the second cladding layer 42 can have a thickness of greater than or equal to 1 nm and less than or equal to 1 μm or greater than or equal to 5 nm and less than or equal to 200 nm or greater than or equal to 10 nm and less than or equal to 60 nm.

In FIG. 3B, based on a simulation corresponding to FIG. 3A, the slope M for a further exemplary simulated light-emitting diode 100 with the cladding layer structure 4 is shown as a function of the thickness D2 of the second cladding layer 42 of SiO₂, wherein a first cladding layer 41 of ITO with a thickness of 10 nm and a third cladding layer 43 of ITO with a thickness of 200 nm were also assumed for the cladding layer structure 4. It can be seen that the slope M increases with increasing thickness D2 of the second cladding layer 42, as the proportion of absorption in the third cladding layer 43 decreases.

In order to shield the optical wave of the light generated in the active layer 3 during operation well from the metallic contact layer 10, the cladding layer structure 4 preferably has a thickness a thickness of greater than or equal to 10 nm and less than or equal to 1 μm or greater than or equal to 50 nm and less than or equal to 400 nm or greater than or equal to 100 nm and less than or equal to 300 nm. The thickness of the cladding layer structure 4 corresponds to a sum of the thickness of the first cladding layer 41 and the thickness of the third cladding layer 43 measured in a second partial region 412, i.e. the distance from the epitaxy top side 20 of the semiconductor layer sequence 2 to the bottom side of the metallic contact layer 10 facing the active region.

At least one or more or each cladding layer of the cladding layer structure 4, i.e. at least one or more or each layer selected from the first cladding layer 41, the second cladding layer 42 and the third cladding layer 43, can comprise one or more of the materials mentioned in each case. If a cladding layer has several materials, these can, for example, be arranged in the form of a layer structure in a vertical direction on top of one another and/or in laterally adjacent areas.

In connection with the following figures, modifications and further embodiments of the light-emitting diode 100 according to FIG. 2 are shown. The following description therefore essentially relates to the differences from the preceding embodiments.

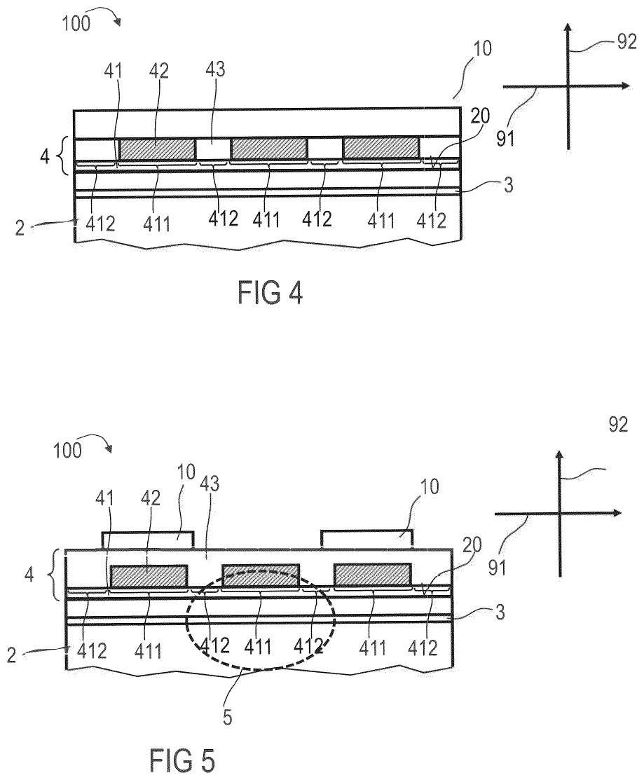

As shown in FIG. 2, the third cladding layer 43 can completely or at least partially cover the second cladding layer 42. As shown in FIG. 4, in contrast to the embodiment of FIG. 2, the third cladding layer 43 can also be arranged only on the at least one second partial region 412 and the at least one first partial region 411 can be free of the third cladding layer 43. In other words, the third cladding layer 43 is not arranged in a vertical direction on the second cladding layer 42. As a result, the second and third cladding layers 42, 43 can have an equal thickness and the third cladding layer 43 is disposed adjacent to regions with the second cladding layer 42 only in the lateral direction. The top side of the cladding layer structure 4 facing away from the active layer 3, on which the metallic contact layer 10 is arranged, can thus be formed by regions with the material of the second cladding layer 42 and regions with the material of the third cladding layer 43.

As an alternative to an arrangement of the metallic contact layer 10 in a large-area manner on the cladding layer structure 4, it can be arranged in a structured manner on the cladding layer structure 4, as shown in FIG. 5. Since the third cladding layer 43 can enable good current extension, the cladding layer structure 4 can thus also be contacted with the metallic contact layer 10 at only one or more points, as indicated in FIG. 5.

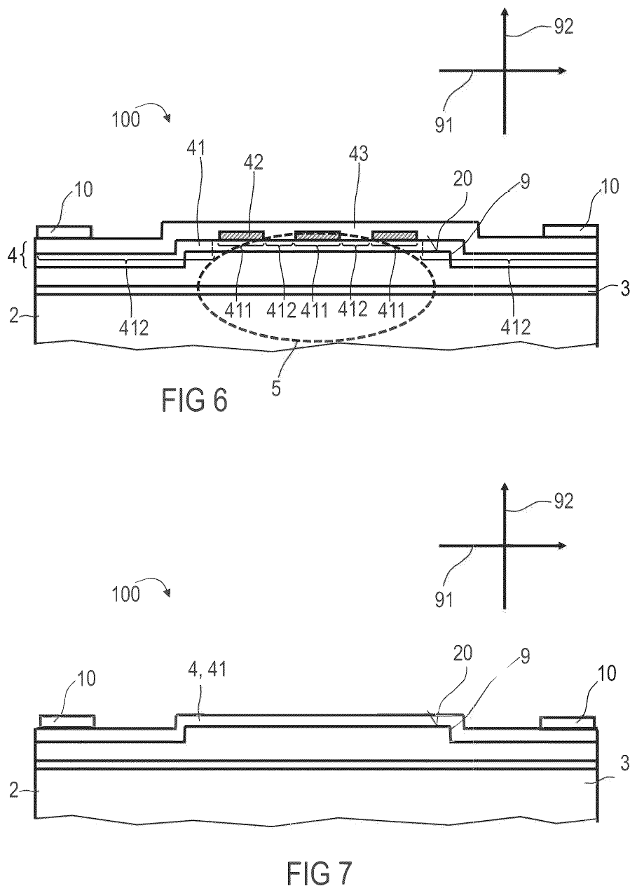

For example, the metallic contact layer 10 can be arranged, in a lateral direction, next to the active region 5 and/or next to the current injection region, as indicated in FIG. 6 purely as an example for a light-emitting diode 100 with a ridge 9. By forming the ridge 9 in the semiconductor layer sequence 2, for example, a good electrical connection of the cladding layer structure 4 to the semiconductor layer sequence 2 can be achieved by a semiconductor contact layer that remains only in the area of the ridge 9 compared to the areas laterally adjacent to the ridge at the top of the ridge 9, so that only this area contributes significantly to the current injection and thus forms the current injection region. As a result of this and the wave guiding by the ridge 9, the formation of the active region 5 can be achieved essentially delimiting it to the region of the ridge 9. In particular for light-emitting diodes that are to be mounted with the p-side up (“p-up”), the metallic contact layer 10 can be provided in the form of one or more contact regions next to the ridge. In this case, for example, the thickness of the third cladding layer 43 can also be further reduced because there is no absorbent metal above the third cladding layer 43. This can make it possible for the surrounding atmosphere, for example air, to act vertically above the active region 5 and thus above the current injection region as part of the cladding layer structure and thus as a further cladding layer.

Furthermore, it can be that in this case the cladding layer structure 4 comprises only the first cladding layer 41 and the light-emitting diode 100 is free of further cladding layers in a vertical direction 92 above the cladding layer structure 4, as indicated in FIG. 7. In other words, the thicknesses of the second cladding layer 42 and the third cladding layer 43 can be reduced, at least almost, to zero. A certain residual thickness can nevertheless be desirable in order to ensure sufficient lateral current transport.

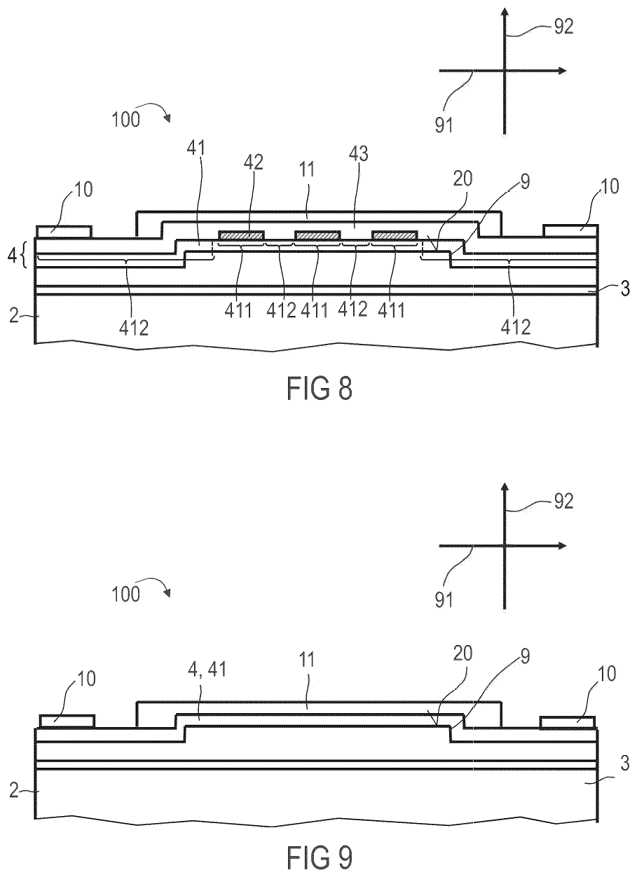

For light-emitting diodes that are to be mounted with the p-side down (“p-down”), the current injection region, for example the ridge 9, can be covered by a dielectric layer 11, for example a dielectric oxide or nitride such as silicon oxide or silicon nitride, as indicated in FIGS. 8 and 9, based on the embodiments of FIGS. 6 and 7. The dielectric layer 11 can act as a further cladding layer, in particular in the event that, as shown in FIG. 9, the cladding layer structure 4 has, at least essentially, only the first cladding layer 41.

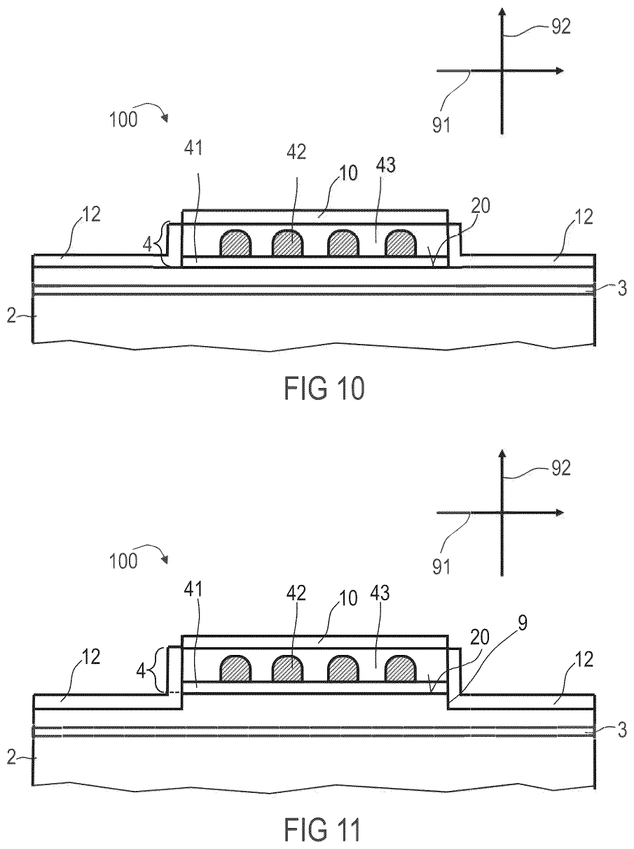

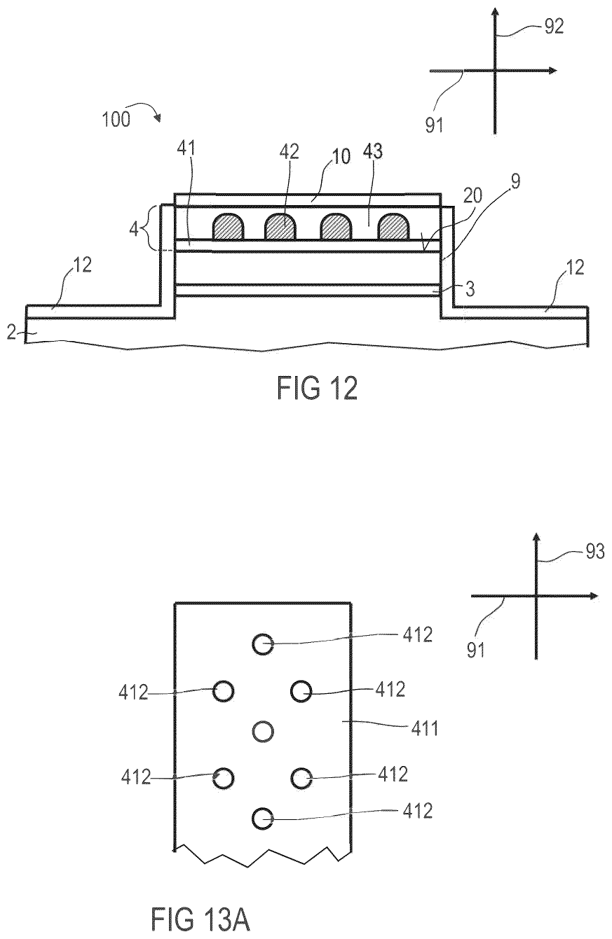

As shown in FIGS. 6 to 9, the cladding layer 4 can also be applied in a large-area manner on the epitaxy top side 20 in the case that a ridge 9 is formed in the semiconductor layer sequence 2. Alternatively, it is also possible that the cladding layer structure 4 is only arranged vertically above the current injection region, as indicated in FIG. 10. A passivation layer 12, for example similar to the previously described dielectric layer, can be applied laterally next to it. In the case of a ridge 9, the cladding layer structure 4 can in particular be arranged on the top side of the ridge 9, as indicated in FIGS. 11 and 12. The light-emitting diodes 100 in FIGS. 11 and 12 differ in terms of their etching depth or ridge height. Whereas in the case of FIG. 11, only the p-side is etched, the etching depth in the case of FIG. 12 extends through the active layer 3 to the n-side of the semiconductor layer sequence 2.

Furthermore, it can be possible that the current injection region does not include edge regions of the top side of the ridge, so that the first cladding layer 41 and thus the cladding layer structure 4 is not applied to the top side of the ridge 9 in edge regions which can be adjacent to side surfaces of the ridge and/or to facets of the semiconductor layer sequence 2. The cladding layer structure 4 can thus be applied to the rest of the entire top side of the ridge except for the said edge regions.

In FIGS. 13A to 13H, examples of the geometric formation of the second cladding layer and thus also of the third cladding layer are indicated on the basis of the distribution of first and second partial regions 411, 412 of the first cladding layer. For example, as shown in FIG. 13A, there can be exactly one first partial region 411 and a plurality of second partial regions 412, wherein the second partial regions 412 are separate from each other and each of the second partial regions 412 is surrounded by the first partial region 411 in a lateral direction. In this case, the second cladding layer is thus configured continuously and has a plurality of openings above the second partial regions 412. Due to a uniform distribution of the openings filled with the material of the third cladding layer, which thus form vias via the second cladding layer, a homogeneous supply with current can be achieved with a low mode selectivity.

By way of example only, FIG. 13A shows second partial regions 412, and thus openings in the second cladding layer, with a circular cross-section. However, these can also have polygonal cross-sections, for example in the form of triangles, squares, rectangles or hexagons. The openings, i.e. the second partial regions 412, can have a size in the lateral direction, in particular a diameter or a width, of less than or equal to 20 μm or less than or equal to 5 μm and of greater than or equal to 1 μm. Particularly preferably, the size can be greater than or equal to 1 μm and less than or equal to 5 μm. Furthermore, the second cladding layer can cover at least 50% or at least 75% or particularly preferably at least 90% and less than 100% of the first cladding layer. Thus, the sum of the surface areas of the first partial region 411 can be at least 50% or at least 75% or more preferably at least 90% as well as less than 100% of the total area of the first cladding layer. The same preferred area coverage can also apply to cases where there are multiple first partial regions.

For example, the trigonally arranged vias shown in FIG. 13A can have a size of 5 μm and a distance of 20 μm transversely and longitudinally or of 16.15 μm to the respective nearest neighbors, so that, for example, there are 15 vias for a length of 100 μm in the longitudinal direction. With an area covered by the cladding layer structure of 1200 μm by 45 μm, this can result in 180 vias, without taking into account deviations at the facets. This results in a coverage of about 93.5% of the area of the first cladding layer with the second cladding layer and a coverage of about 6.5% with the third cladding layer for electrical contacting.

The arrangements of first and second partial regions 411, 412 shown in FIG. 13A and in FIGS. 13B to 13H can also be reversed. Thus, in the case of the arrangement shown in FIG. 13A, there can also be exactly one second partial region and a plurality of first partial regions, the first partial regions being separate from each other and each of the first partial regions being surrounded by the second partial region in the lateral direction. In this case, the second cladding layer is thus formed in the form of a plurality of islands, which are separated from one another on the first cladding layer by the configured continuously second partial region. The geometric configuration of the islands can be as described for the openings.

As shown in FIG. 13B, edge regions can also form, for example, second partial regions 412 in order to achieve a supply with current, for example, on ridge sides or in the region of the facets. Conversely, the edge regions can also form first partial regions 411, for example, in order to reduce the supply with current in these regions.

Furthermore, at least one or more or each of the openings or islands can be formed in a strip-like manner with a main direction of extension in a longitudinal or transversal direction, i.e. as longitudinal or transverse strips. In FIG. 13C, second partial regions 412 are formed as longitudinal strips that preferably do not extend to a facet. Increased mode selectivity can be achieved by constant strip-like structures in the transversal direction 92, for example with a preferred width of greater than or equal to 1 μm and less than or equal to 5 μm. For example, with a 45 μm wide cladding layer structure, for example on a ridge top surface, 5 μm wide strips can be formed so that approximately 5/9 of the area of the first cladding layer 41 is in contact with the third cladding layer as shown. Interchanging the first and second partial regions 411, 412, at least in the area of the strips, would then lead to a corresponding occupancy of 4/9.

As shown in FIG. 13D, individual second partial regions 412 can for example also extend to the facet, so that, for example on a top side of the ridge, a supply with current to the facet can only be achieved in a partial region. This can advantageously achieve better pumping of the facet area, which can result in a greater steepness, while less pumping occurs at the ridge edges, which can reduce the risk of damage or failures, for example due to COD (“catastrophic optical damage”).

In FIG. 13E, a honeycomb-like structure is shown, that is, the first and second partial regions 411, 412 are composed of honeycomb-like partial regions, which are partially indicated. The distribution of the first and second partial regions 411, 412 has a focus on the center in order to avoid supplying too much current to the edge. For example, with 5 μm wide honeycombs at a width of 45 μm in the transversal direction 92, the second partial region 412 occupies an area of about 33% in the configuration shown.

As shown, the openings or islands in the second cladding layer, i.e. correspondingly the second partial regions or the first partial regions, can be arranged uniformly in the longitudinal and/or transversal direction, i.e. with the same sizes and/or the same cross-sectional shapes and the same spacings from one another. The openings or islands, i.e. correspondingly the second partial regions or the first partial regions, can thus be arranged as shown, for example, in a regular dot pattern or a regular striped pattern. Alternatively, the openings or islands, i.e. correspondingly the second partial regions or the first partial regions, can be irregularly shaped, i.e. have different sizes and/or different distances from each other and/or different cross-sectional shapes, as indicated in FIG. 13F. In this way, unwanted mode and wavelength selection can be avoided.

Furthermore, a plurality of second partial regions 412 can also be present, wherein the second partial regions 412 are regularly spaced in longitudinal directions by a distance corresponding to an integer multiple of half a wavelength of the light generated in the active layer, taking into account the effective refractive index, as indicated in FIGS. 13G and 13H. This can make it possible to prefer and/or stabilize certain wavelengths. For example, for GaN with a wavelength of the light emitted of 450 nm and the 10th order, a period of about 900 nm would result.

As an alternative to the vertically energized versions of the light-emitting diode 100 shown, it can also be configured, for example, in the form of a so-called flip-chip structure with metallic contact layers 100 arranged next to each other on the same side for bi-directionally emitting contact with the semiconductor layer sequence 2 as seen from the active layer 3, as indicated in FIG. 14. For this purpose, a part of the semiconductor layer sequence 2 can be etched through a trench to below the active layer 3 for electrical separation. The trench can, for example, be electrically insulated by means of a passivation layer 12.

The embodiments and features shown in the figures are not limited to the combinations shown in the figures. Rather, the shown embodiments as well as individual features can be combined with one another, even if not all possible combinations are explicitly described. In addition, the embodiments described in the figures can alternatively or additionally have further features as described in the general part.

The invention is not limited by the description based on the embodiments to these embodiments. Rather, the invention includes each new feature and each combination of features, which includes in particular each combination of features in the patent claims, even if this feature or this combination itself is not explicitly explained in the patent claims or embodiments.

1. A light emitting diode, comprising:
a semiconductor layer sequence grown in a vertical direction with an active layer which is configured and intended to generate light in an active region during operation, and
a transparent, at least partially electrically conducting cladding layer structure, which is arranged directly on the semiconductor layer sequence in the vertical direction,
wherein
the cladding layer structure has at least a first cladding layer, a second cladding layer and a third cladding layer,
the first cladding layer is arranged directly on the semiconductor layer sequence on at least one current injection region and has a first thickness which is less than or equal to 200 nm,
the second cladding layer is arranged directly on the first cladding layer and is structured so that the first cladding layer is covered by the second cladding layer in at least a first partial region and is uncovered by the second cladding layer in at least a second partial region, and
the third cladding layer is arranged directly on the first cladding layer at least in the at least one second partial region and directly on the second cladding layer over the at least one first partial region.

2. The light emitting diode according to claim 1, wherein the first cladding layer has a thickness of less than or equal to 70 nm or less than or equal to 30 nm.

3. The light emitting diode according to claim 1, wherein the first cladding layer is applied unstructured to the current injection region.

4. The light emitting diode according to claim 1, wherein the first cladding layer is applied in a large-area manner and unstructured on an entire epitaxy top side of the semiconductor layer sequence facing away from the active layer.

5. The light emitting diode according to claim 1, wherein the current injection region is formed by at least a part of a ridge in the semiconductor layer sequence at an epitaxy top side facing away from the active layer.

6. The light emitting diode according to claim 1, wherein the third cladding layer is arranged only on the at least one second partial region and the at least one first partial region is free of the third cladding layer.

7. The light emitting diode according to claim 1, wherein a metallic contact layer is arranged directly on the cladding layer structure.

8. The light emitting diode according to claim 7, wherein the metallic contact layer is arranged in a lateral direction next to the active region only.

9. The light emitting diode according to claim 8, wherein only one dielectric layer is arranged on the cladding layer structure in the vertical direction above the active region, or the cladding layer structure is directly adjacent to the surrounding atmosphere in a vertical direction above the active region.

10. The light emitting diode according to claim 1, wherein the second cladding layer has a thickness of less than or equal to 1 μm.

11. The light emitting diode according to claim 1, wherein the cladding layer structure has a thickness of greater than or equal to 10 nm and less than or equal to 1 μm.

12. The light emitting diode according to claim 1, wherein the second cladding layer is embodied continuously with a plurality of openings.

13. The light emitting diode according to claim 12, wherein the openings have different sizes and/or distances from each other and/or cross-sectional shapes.

14. The light emitting diode according to claim 1, wherein the second cladding layer covers at least 50% and less than 100% of the first cladding layer.

15. The light emitting diode according to claim 1, wherein the first cladding layer and/or the third cladding layer comprises a transparent conductive oxide and/or a non-epitaxially deposited semiconductor material.

16. The light emitting diode according to claim 1, wherein the second cladding layer comprises a dielectric material.

17. The light emitting diode according to claim 1, wherein the second cladding layer
has an absorption coefficient of less than or equal to 500/cm and/or
has an absorption coefficient and a refractive index which are smaller than an absorption coefficient and a refractive index of the first cladding layer.

18. A light emitting diode, comprising:
a semiconductor layer sequence grown in a vertical direction with an active layer which is configured and intended to generate light in an active region during operation, and
a transparent, at least partially electrically conducting cladding layer structure, which is arranged directly on the semiconductor layer sequence in the vertical direction,
wherein
the cladding layer structure has at least a first cladding layer,
the first cladding layer is arranged in a large-area manner directly on the semiconductor layer sequence and has a first thickness which is less than or equal to 200 nm,
the first cladding layer has a transparent conductive oxide,
a metallic contact layer is arranged in a structured manner directly on the cladding layer structure,
the metallic contact layer is arranged in a lateral direction next to the active region only, and
only one dielectric layer is arranged directly on the cladding layer structure in the vertical direction above the active region or the cladding layer structure is directly adjacent to the surrounding atmosphere in the vertical direction above the active region.

19. The light emitting diode according to claim 18, wherein the cladding layer structure comprises only the first cladding layer.
